(19) United States
(12) Patent Application Publication
(10) Pub. No.: US 2003/0134451 A1
(43) Pub. Date: Jul. 17, 2003

(54) Structure and process for packaging back-to-back chips

(75) Inventor: Tsung-Chieh Chen, Taipei (TW)

Correspondence Address: BRUCE H. TROXELL, SUITE 1404, 5205 LEESBURG PIKE, FALLS CHURCH, VA, 22041, US

(73) Assignee: PICTA TECHNOLOGY, INC.

(21) Appl. No.: 10/043,122

(22) Filed: Jan. 14, 2002

(51) Int. Cl. H01L 21/44

(52) U.S. Cl. 438/109

(57) ABSTRACT

A packaging structure for back-to-back chips, which includes: a substrate, a first chip, a second chip, and an encapsulation. Wherein, the first chip has an active side and an inactive side, and the active side of the first chip is connected to the substrate by an adhesion layer and conducted electrically with the substrate by wire-bonding. The second chip has an active side that is also conducted electrically with the substrate by wire-bonding and an inactive side that is connected to the inactive side of the first chip by another adhesion layer. The encapsulation covers both the first chip and the second chip for protecting the back-to-back packaging structure.

### FIELD OF THE INVENTION

The invention relates to a structure and process for packaging back-to-back chips, particularly to the packaging structure and process for adhering two chips with same size or different sizes by the back-to-back manner under the condition of no spacer.

### BACKGROUND OF THE INVENTION

In the prior arts, the stack packaging techniques for semiconductor chips all adopt the manner that the back side of the upper chip is adhered to the front side of the lower chip. That is, the back side of the upper chip is adhered onto the circuit layer of the lower chip. Wherein, the applied adhesive material with no conductance will be severed as the adhesion layer between the upper chip and the lower chip.

The most common seen structure for packaging chips is the side-by-side structure for packaging chips, which arranges two chips side by side to each other on the main arranging side of a common substrate. The conduction between the chip and the substrate is achieved by wire-bonding method.

As shown in FIG. 1A, which is an illustration for the stack packaging structure for semiconductor chips according to the prior arts, which includes a lower chip 110 that is arranged on a substrate 120 and is electrically connected to the substrate 120, and an upper chip 130 that is stacked on the lower chip 110 and is also electrically connected to the substrate 120. In order to prevent the loops of the bonding wires from being crashed down, that is, prevent the wire 150 from being crashed down, so the size of the upper chip 130 must be smaller than that of the lower chip 110, and that limitation restricts the scope of application.

In the prior arts, a wire interconnection of wire bonding technique formed between the chip pad and the substrate pad generally includes: a ball bond arranged on the chip pad, a loop formed between the chip pad and the substrate pad, and a stitch bond arranged to the substrate pad, for completing the connection for bonding wire. In general, the loop height is about 10 to 15 mil. Although, by adjusting the loop factor, appearance, and formation, the wire bonding technique of prior arts may reduce the loop height as low as 6 mil, but this is the least loop height already obtainable, because the further lower loop height will damage the wire and weaken the tension.

Therefore, in order to stack the chips of same size, a manner shown in FIG. 1B is applied, wherein it also includes a lower chip 110 that is arranged on a substrate 120 and is connected electrically to the substrate 120, and an upper chip 130 having same size as the lower chip 110 is stacked on the lower chip 110 and is also connected electrically with the substrate 120. It is characterized of applying a spacer 140 arranged between these two chips for providing a desired clearance for the loops of the wire 150. In addition, the spacer 140 made of conductive material of metal may also be served as grounding face for the semiconductor chips and provide an arrangement of capacitance. Although, the application of a spacer 140 already solves the problem of stacking chips of same size but, since the size of the spacer must be smaller than that of the actual chip so, after an upper chip being stacked, a suspension zone will be generated. When wire-bonding the upper chip, this kind of structure will cause a difficulty on process and incur a displacement that will be resulted in inaccuracy, lower product yield and further influence on competition capability.

So, the aforementioned techniques according to prior arts can't really satisfy the future trend and requirement for size shrinkage and cost down for semiconductor element. There is still a room remaining for improvement.

### SUMMARY OF THE INVENTION

The main object of the invention is to provide a structure and process for packaging back-to-back chips to complete the stack of two chips with same size or a pad therein under the condition of no spacer.

A further object of the invention is to provide a structure and process for packaging back-to-back chips, and the packaging manner of the invention is always applicable to the chip whose pads are located anywhere thereon.

A still further object of the invention is to provide a structure and process for packaging back-to-back chips for making the wire-bonding be easier to control.

Another still further object of the invention is to provide a structure and process for packaging back-to-back chips for making the packaging structure be further lighter and further thinner.

Another still further object of the invention is to provide a structure and process for packaging back-to-back chips for eliminating the complexity of process.

In order to achieve above-mentioned objects, a packaging structure for back-to-back chips is therefore provided, wherein it includes: a substrate, a first chip, a second chip, and an encapsulation. Wherein, the first chip has an active side and an inactive side, and the active side of the first chip is partially combined with the substrate and is electrically conducted with the substrate by wire-bonding; the second chip also has an active side and an inactive side, and the inactive side of the second chip is combined with the inactive side of the first chip, while the active side of the second chip is conducted electrically with the substrate by wire-bonding; the encapsulation, covering the first chip and the second chip for protecting the packaging structure for back-to-back chips. Plural solder balls may be further arranged on the substrate for coupling other circuit board by said solder balls.

Preferably, the packaging process for back-to-back chips includes following steps:

a) Providing a first chip, a second chip and a substrate, wherein the first chip and the second chip having an active side and an inactive side respectively;

b) Combining the active side of the first chip partially with the substrate;

c) Conducting the active side of the first chip to the substrate by wire-bonding;

d) Combining the inactive side of the second chip with the inactive side of the first chip;

e) Conducting the active side of the second chip to the substrate by wire-bonding.

Preferably, after the “step e”, several steps are further included as follows:

a) Covering the first chip and the second chip by an encapsulation for protecting the packaging structure for back-to-back chips;

b) Arranging plural solder balls on the substrate for coupling other circuit board by said solder balls.

For your esteemed reviewing committee to further understand and recognize the objects, characteristics, and functions of the present invention, a detailed description in cooperation with corresponding drawings are presented as follows.

### BRIEF DESCRIPTION OF THE DRAWINGS

FIG. 1A is an illustration for the packaging structure for stacking semiconductor chips according to the prior arts.

FIG. 1B is an illustration for the packaging structure for stacking semiconductor chips according to the prior arts.

FIG. 2 is an illustration for the first preferable embodiment of the structure and process for packaging back-to-back chips according to the present invention.

FIG. 3A through FIG. 3F are the illustrations for the flow path of a preferable process embodiment for the first preferable embodiment for the packaging structure for back-to-back chips shown in FIG. 2.

FIG. 4 is an illustration for the second preferable embodiment of the structure and process for packaging back-to-back chips according to the present invention.

FIG. 5 is an illustration for the third preferable embodiment of the structure and process for packaging back-to-back chips according to the present invention.

FIG. 6 is an illustration for the fourth preferable embodiment of the structure and process for packaging back-to-back chips according to the present invention.

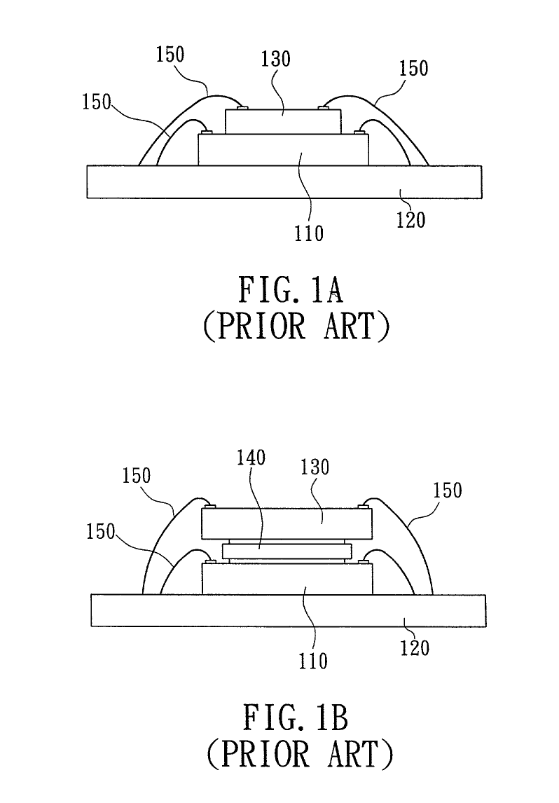

### DETAILED DESCRIPTION OF THE PREFERRED EMBODIMENT

The invention relates to a structure and process for packaging back-to-back chips, wherein two chips with same size or different sizes are stacked to a formation by the back-to-back manner. For packaging the chips with same size or pads in the center, using the back-to-back manner can make the entire packaging process without the application of any spacer, so the packaging thickness can be reduced effectively.

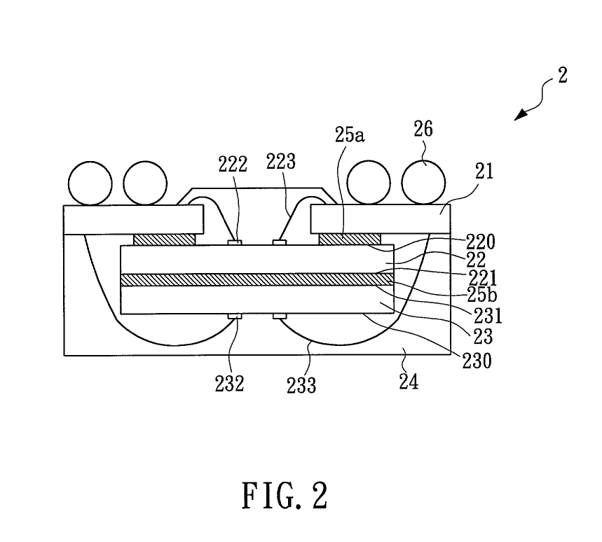

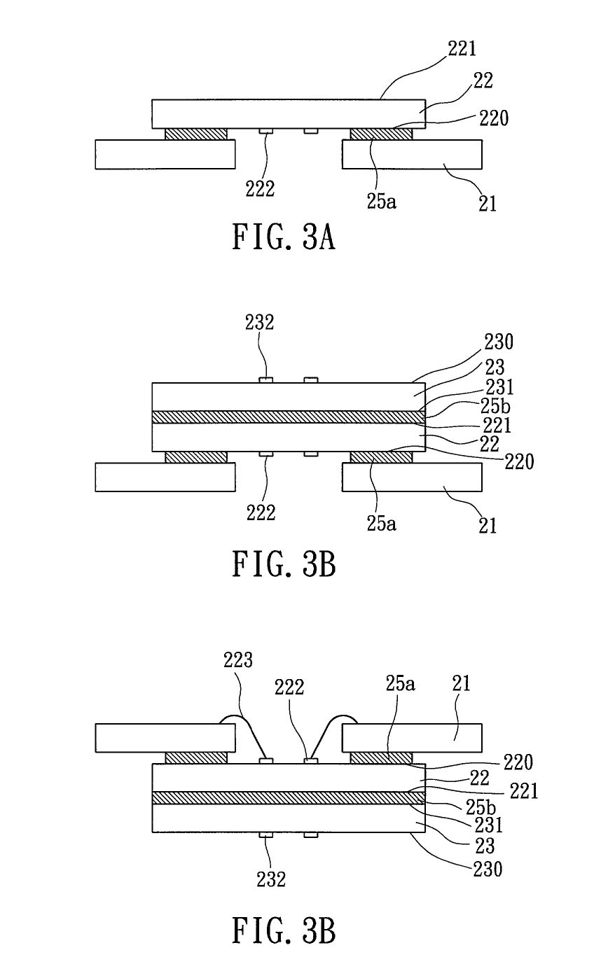

Please refer to FIG. 2, which is an illustration for the first preferable embodiment for the packaging structure for back-to-back chips according to the present invention, while FIG. 3A through FIG. 3F is a preferable flow path embodiment for the process steps of the first preferable embodiment shown in FIG. 2.

In the first preferable embodiment shown in FIG. 2, wherein the packaging structure for back-to-back chips 2 includes: a substrate 21, a first chip 22, a second chip 23, and an encapsulation 24. Wherein, the first chip 22 has an active side 220 and an inactive side 221. The active side 220 is a side surface where the circuit design of the first chip 22 is located, and the active side 220 of the first chip 22 is partially connected onto the substrate 21 by adhesion layers 25a. Further, plural pads 222 arranged in the central position of the active side 220 of the first chip 22 are served as the interface between the circuit on the first chip 22 and the outside. The second chip 23 also has an active side 230 and an inactive side 231. The active side 230 is also a side surface where the circuit design of the second chip 23 is located, and the inactive side 231 of the second chip 23 is connected to the inactive side 221 of the first chip 22 by an adhesion layer 25b. Further, plural pads 232 are also arranged in the central position of the active side 230 of the second chip 23 for serving as the interface between the circuit on the second chip 23 and the outside. In this preferable embodiment, the pads 222, 232 are the commonly so-called metal pad or A1 pad. The encapsulation 24 covers the first chip 22 and the second chip 23 for protecting the packaging structure for back-to-back chips 2. Plural solder balls 26 may be arranged on the substrate for coupling the structure 2 with other circuit board by said solder balls 26.

The plural pads 222, 232 arranged on the active side 220 of the first chip 22 and on the active side 230 of the second chip 23 are conducted electrically with the substrate 21 by wire 223, 233. In this preferable embodiment, the adhesion layers 25a, 25b may adopt the adhesive materials such as dual-sided adhesive tape, silver glue, and epoxy, etc.

With the back-to-back structure as shown in FIG. 2, since both the first chip 22 and the second chip 23 all adopt its inactive side for interconnection, so the packaging structure for back-to-back chips 2 according to the present invention may complete the stacking process for the chips with same size or the pads in the center under the condition of no spacer. And, the packaging manner of the invention may be applied for the chip whose pads could be located anywhere thereon. The first chip 22 and the second chip 23 may be two chips with different functions. For example, the first chip 22 may be a chip of logic circuit, while the second chip 23 is a chip of memory circuit. Therefore, several kinds of chips containing different functions may be coexisted in one single IC for greatly enhancing the design and application flexibility thereof. Of course, after referring aforementioned description, those skilled in the semiconductor technology should easily conceive that both the first chip 22 and the second chip 23 may be two chips with same function.

In the following embodiments, of which element bearing the same function as the element of aforementioned embodiments will be designated with same referential number and name, and its function will not be described repetitiously herein any more.

Please refer to FIG. 3A through FIG. 3F, which is a preferable flow path embodiment for the processing steps for the packaging structure for back-to-back chips 2 shown in FIG. 2, wherein it includes following steps:

a). Provide a substrate 21, a first chip 22, and a second chip 23, wherein the first chip 22 and the second chip 23 each has an active side 220, 230 and an inactive side 221, 231 respectively, and plural pads 222, 232 are arranged at the central position of each active side 220, 230.

b). Connect the active side 220 of the first chip 22 partially on the substrate and avoid the pads 222 on the active side 220.

c). By wire-bonding, making the circuit on the first chip 22 be able to conduct electrically to the substrate 21 with the wire 223, while the substrate 21 is further conducted electrically with the outside.

d). Connect the inactive side 231 of the second chip 23 onto the inactive side 221 of the first chip 22, at this time, since it is a connection between the inactive side 221 and the inactive side 231, that is, a connection of back-to-back type, so no matter where the pads 222, 232 are positioned on the active side 220, 230, the process won't be influenced and the complexity of the process is also eliminated, of course.

e). By wire-bonding, making the circuit of the second chip 23 may be conducted electrically with the substrate 21 through the wire 233, while the substrate 21 is further conducted electrically with the outside.

f). Then, apply an encapsulation 24 to cover the first chip 22 and the second chip 23 for protecting the packaging structure for back-to-back chips 2.

g). Arrange plural solder balls 26 on the substrate 21 for coupling with other circuit board by said solder balls 26.

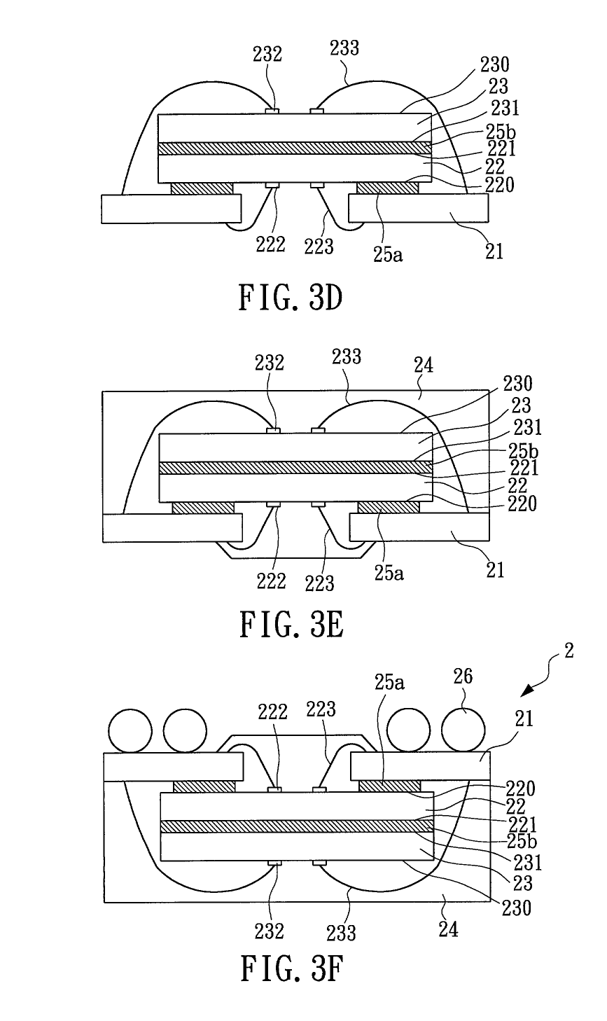

Please refer to FIG. 4, which is an illustration for the second preferable embodiment for the packaging structure for back-to-back chips according to the present invention.

In the second preferable embodiment shown in FIG. 4, the packaging structure for back-to-back chips 3 is also that the first chip 32 is partially connected onto the substrate 31 with an adhesion layer 35 to make the circuit on the first chip 32 be able to conduct electrically with the substrate 31 by wire-bonding. Afterwards, make the inactive side 331 of the second chip 33 be connected onto the inactive side 321 of the first chip 32 for completing the packaging structure 3 for back-to-back chips. Wherein, the pads 332 on the active side 330 of the second chip are positioned on the circumference of the active side 330 without influencing the flow path for wire bonding control and multi-chip stack. Therefore, the yield and speed of the process can be further increased effectively without the need for more repetitious description herein.

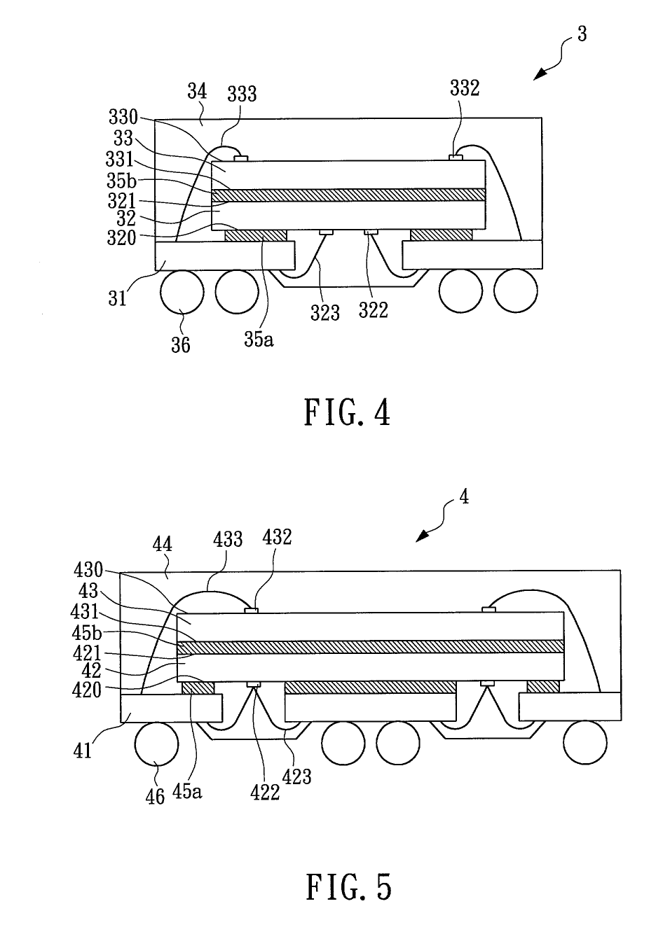

As shown in FIG. 5, which is an illustration for the third preferable embodiment for the structure and process for packaging back-to-back chips according to the present invention. In this packaging structure for back-to-back chips 4, the first chip 42 and the second chip 43 are also connected by the back-to-back manner. Wherein, the pads 422, 432 on the active sides 420, 430 are all located on the circumferences of two chips for completing the process for packaging the back-to-back chips, and its advantages are not repetitiously presented herein either.

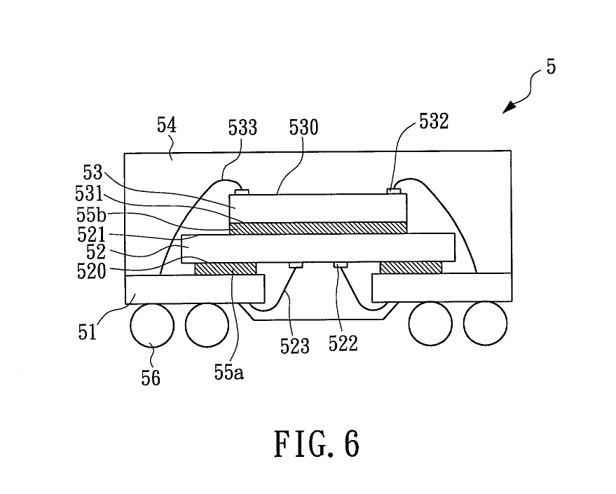

As shown in FIG. 6, which is an illustration for the fourth preferable embodiment for the structure and process for packaging back-to-back chips according to the present invention. In this packaging structure for back-to-back chips 5, the first chip 52 and the second chip 53 are also connected together by the back-to-back manner too. Wherein, since the size of the second chip 53 is smaller than that of the first chip 52, so they can also be packaged together by the back-to-back manner.

In summary, the structure and process for packaging back-to-back chips according to the present invention are mainly to stack two chips with same size or different sizes together into a formation by the back-to-back manner. The packaging manner according to the present invention may be applied for the chips whose pads are located anywhere thereon. For the chips whose sizes are same or with pads therein, the application of spacer is not needed, so the particle thickness after entire packaging process is reduced effectively, the packaging structure is made further lighter and further thinner, the complexity of process is eliminated, and the wire bonding manner is made further easy to control.

Also, the structure and process for packaging back-to-back chips according to the present invention may also choose two chips with different functions (or choose two same chips) in one single IC simultaneously for enhancing the design and application flexibility of IC greatly, simplifying its entire structure, reducing its volume, area, and length, making the process more easy, and also lowering down the manufacturing cost.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A packaging structure for back-to-back chips, including:
a substrate;
a first chip, having an active side and an inactive side, and the active side of the first chip partially combining with the substrate and conducted with the substrate by wire-bonding;
a second chip, having an active side and an inactive side, and the inactive side of the second chip combining with the inactive side of the first chip, while the active side of the second chip conducted with the substrate by wire-bonding; and
an encapsulation, covering the first chip and the second chip for protecting the packaging structure for back-to-back chips.

2. The packaging structure for back-to-back chips as recited in claim 1, wherein the combination between the first chip and the substrate is made by the adhesion manner of an adhesion layer.

3. The packaging structure for back-to-back chips as recited in claim 1, wherein the combination between the second chip and the first chip is made by the adhesion manner of an adhesion layer.

4. The packaging structure for back-to-back chips as recited in claim 1, wherein the first chip and the second chip are the chips with same size.

5. The packaging structure for back-to-back chips as recited in claim 1, wherein the first chip and the second chip are the chips with different size.

6. The packaging structure for back-to-back chips as recited in claim 1, wherein the first chip and the second chip are the chips with same function.

7. The packaging structure for back-to-back chips as recited in claim 1, wherein the first chip and the second chip are the chips with different function.

8. The packaging structure for back-to-back chips as recited in claim 1, wherein arranged plural solder balls are on the substrate and the packaging structure for back-to-back chips is coupled with a circuit board by the solder balls.

9. A packaging process for back-to-back chips as claim 1, comprising following steps:
a) providing a first chip, a second chip and a substrate, wherein the first chip and the second chip having an active side and an inactive side respectively;
b) combining the active side of the first chip partially with the substrate;
c) conducting the active side of the first chip to the substrate by wire-bonding;
d) combining the inactive side of the second chip with the inactive side of the first chip;
e) conducting the active side of the second chip to the substrate by wire-bonding.

10. The packaging process for back-to-back chips as recited in claim 9, wherein, after the “step e”, several steps are further included as follows:
f) covering the first chip and the second chip by an encapsulation for protecting the packaging structure for back-to-back chips;
g) arranging plural solder balls on the substrate for coupling other circuit board by said solder balls.

11. The packaging process for back-to-back chips as recited in claim 9, wherein the combination between the first chip and the substrate is made by the adhesion manner of an adhesion layer.

12. The packaging process for back-to-back chips as recited in claim 9, wherein the combination between the second chip and the first chip is made by the adhesion manner of an adhesion layer.

13. The packaging structure for back-to-back chips as recited in claim 9, wherein the first chip and the second chip are the chips with same size.

14. The packaging structure for back-to-back chips as recited in claim 9, wherein the first chip and the second chip are the chips with different size.

15. The packaging structure for back-to-back chips as recited in claim 9, wherein the first chip and the second chip are the chips with same function.

16. The packaging structure for back-to-back chips as recited in claim 9, wherein the first chip and the second chip are the chips with different function.
